(19) United States
(12) Patent Application Publication
(10) Pub. No.: US 2025/0026888 A1
(43) Pub. Date: Jan. 23, 2025

(54) PARTICLE COMPOSITION, FILM, OPTICAL LENS, DIFFRACTIVE OPTICAL ELEMENT, ION CONDUCTIVE MEMBRANE, BATTERY SEPARATOR FILM, SECONDARY BATTERY, CIRCUIT BOARD, AND DIAPHRAGM

(71) Applicant: TORAY INDUSTRIES, INC., Tokyo (JP)

(72) Inventors: Hiroyoshi HAMADA, Otsu-shi, Shiga (JP); Akimitsu TSUKUDA, Otsu-shi, Shiga (JP)

(73) Assignee: TORAY INDUSTRIES, INC., Tokyo (JP)

(21) Appl. No.: 18/715,568

(22) PCT Filed: Dec. 21, 2022
(86) PCT No.: PCT/JP2022/047047

§ 371 Date: May 31, 2024

(30) Foreign Application Priority Data
Feb. 9, 2022 (JP) 2022-018451

(51) Int. Cl. C08G 73/10; C08J 5/22; G02B 1/04; H01M 50/423; H05K 1/03

(52) U.S. Cl. CPC C08G 73/1067; C08J 5/2256; G02B 1/041; H01M 50/423; H05K 1/0353; C08J 2379/08

(57) ABSTRACT

The present disclosure provides a resin composition containing an aromatic polyamide and/or an aromatic polyamic acid.

### TECHNICAL FIELD

The present invention relates to a particle composition containing an aromatic polyamide and/or an aromatic polyamic acid, as a major component(s), as well as a film, an optical lens, a diffractive optical element, an ion conductive membrane, a battery separator film, a secondary battery, a circuit board and a diaphragm comprising the particle composition.

### BACKGROUND ART

Aromatic polyamides and aromatic polyimides obtained from aromatic polyamic acids play important roles, as materials to be used in the industries of fibers, electronic devices, automobiles and the like, because of their excellent mechanical properties and heat resistance. In the case of producing a member composed of an aromatic polyamide-based resin, a solution or a powder is used because of the ease of handling and formation.

Excellent physical properties of aromatic polyamides and/or aromatic polyamic acids are derived from a strong intermolecular interaction due to the r-r interaction between aromatic groups and hydrogen bonding between amide groups. On the other hand, these polymers have a low dispersibility and solubility in the state of a solid and are poor in processability.

An improvement in the workability of particle compositions has been studied. For example, Patent Literatures 1 and 2 each discloses a polyimide resin precursor powder in which the degree of polymerization and the imidization rate are controlled.

In contrast, Patent Literature 3 discloses, for example, polymer fine particles in which the particle-size distribution and the particle size are controlled. Further, Patent Literature 4 discloses, for example, a method of producing a polyamide-based resin powder having a small particle-size distribution.

### CITATION LIST

### Patent Literatures

Patent Literature 1: JP 5-271539 A
Patent Literature 2: JP 2020-12103 A
Patent Literature 3: JP 2013-237857 A
Patent Literature 4: JP 2021-113275 A

### SUMMARY OF INVENTION

### Technical Problem

However, in the resin powder disclosed in Patent Literature 1 or 2, the molecular structure of the polyamic acid is limited due to improvement of the processability (dispersibility and solubility in a solvent), and the application to an aromatic polyamide having a high rigidity is difficult.

Further, the polymer fine particles disclosed in Patent Literature 3 are produced in an emulsion of a good solvent and a poor solvent that undergo phase separation in order to control the shape of the particles of the resulting powder. In this case, contact of the polymer with the poor solvent may cause sudden aggregation, possibly resulting in a failure to obtain a powder. Therefore, the polymers available in this case are limited to resins with high solubility such as amorphous non-wholly aromatic polyamides and polyetherimides.

Further, the production method disclosed in Patent Literature 4, where the stirring speed and the rate of addition of a poor solvent are used for controlling the particle size, tends to make the particle size of the resulting resin powder relatively larger, possibly causing a decrease in the solubility or an increase in the amount of contained impurities.

In addition, in each of Patent Literatures 1 to 4 the powder or the fine particles need(s) to be handled as one/those with a small particle size from the time of the production. This may lead to a decrease in processability, such as the occurrence of the clogging of a filter cloth or the scattering of the powder.

An object of the present invention is to provide a particle composition that has an excellent dispersion solubility and handleability even in the case of containing, as a major component(s), an aromatic polyamide and/or an aromatic polyamic acid having a low solubility and a high cohesion and which is capable of producing fibers, a molded product, a film and the like having a high performance; and a film, an optical lens, a diffractive optical element, an ion conductive membrane, a battery separator film, a secondary battery, a circuit board and a diaphragm comprising the particle composition.

### Solution to Problem

To achieve the above-mentioned objective, the present invention is characterized by the following.

(1) A particle composition containing an aromatic polyamide and/or an aromatic polyamic acid
wherein the ratio r_{A}/r_{B} is larger than 1, and r_{B} is 100 nm or more and 10,000 nm or less in which r_{A} (nm) is an average hydrodynamic radius of particles as measured by a dynamic light scattering method in an aqueous dispersion containing said particle composition at a concentration of 100 ppm by mass, and r_{B} (nm) is said average hydrodynamic radius after subjecting the aqueous dispersion to an ultrasonic treatment.
   (2) The particle composition according to claim 1,
wherein the particle composition comprises the aromatic polyamide, r_{A}/r_{B} is 3 or more, and r_{B} is 100 nm or more and 5,000 nm or less.
   (3) The particle composition according to (1) or (2), wherein a Brunauer-Emmett-Teller (BET) surface area of the particle composition as measured by a gas adsorption method is 50 m²/g or more and 90 m²/g or less.
   (4) The particle composition according to any one of (1) to (3), wherein, M_{w}/Mₙ is 1.0 or more and 2.5 or less, in which Mₙ is a number average molecular weight as measured by gel permeation chromatography (GPC), and M_{w} is a mass average molecular weight as measured by GPC.
   (5) A film comprising the particle composition according to any one of (1) to (4).
   (6) An optical lens comprising the particle composition according to any one of (1) to (4).
   (7) A diffractive optical element comprising the particle composition according to any one of (1) to (4).
   (8) An ion conductive membrane comprising the particle composition according to any one of (1) to (4).
   (9) A battery separator film comprising the particle composition according to any one of (1) to (4).
   (10) A secondary battery containing the ion conductive membrane according to (8).
   (11) A circuit board comprising the particle composition according to any one of (1) to (4).
   (12) A diaphragm comprising the particle composition according to any one of (1) to (4).
   (13) The particle composition according to claim 1, wherein the aromatic polyamide is a major component in the particle composition.
   (14) The particle composition according to claim 1, wherein the aromatic polyamic acid is a major component in the particle composition.
   (15) The particle composition according to claim 1, wherein a concentration of the aromatic polyamide is 70% by mass or more.
   (16) The particle composition according to claim 1, wherein a concentration of the aromatic polyamic acid is 70% by mass or more.
   (17) The particle composition according to claim 1, wherein a total concentration of the aromatic polyamide and the aromatic polyamic acid is 70% by mass or more.

### Advantageous Effects of Invention

According to the present invention, it is possible to provide a particle composition containing an aromatic polyamide and/or an aromatic polyamic acid as a major component(s), which composition has an excellent dispersibility. Therefore, the particle composition according to the present invention enables a balance between the handleability and the solubility of the powder, making it possible to obtain fibers, a molded product, a film and the like having a high rigidity and a high heat resistance, and with a low amount of impurities, even in the case of using an aromatic polyamide and/or an aromatic polyamic acid having a low solubility and a high cohesion.

According to the present invention, it is possible to provide a film with low contents of low-molecular-weight components and impurities. Therefore, a film, a laminated body or the like having an excellent rigidity and long-term stability can be obtained.

According to the present invention, it is possible to provide an optical lens and/or a diffractive optical element having an excellent transparency and shape stability. Therefore, in cases where the optical lens and/or the diffractive optical element according to the present invention is/are used as a lens for a sensor and/or an optical wave-guide element for an AR device, for example, it is possible to produce a sensor and/or a device having an excellent sensitivity and luminance.

According to the present invention, it is possible to provide an ion conductive film and/or a battery separator film with a low amount of impurities and having an excellent mechanical strength. In cases where the ion conductive film and/or the battery separator film according to the present invention is/are used in a secondary battery, for example, excellent battery characteristics can be obtained since the ion conductive film and the battery separator film provide excellent safety because of their heat resistance, deformation and impact resistance and the like, and are each a low-resistance thin film.

According to the present invention, it is possible to provide a circuit board having an excellent heat resistance and dimensional stability.

According to the present invention, it is possible to provide a diaphragm having an excellent rigidity and creep properties. Therefore, in cases where the diaphragm is used in an acoustic speaker, an actuator, a microphone or the like, for example, excellent transient characteristics as well as an excellent output and/or sensitivity in the high-frequency range to the ultrasonic range can be obtained.

### DESCRIPTION OF EMBODIMENTS

The particle composition according to the present invention contains an aromatic polyamide and/or an aromatic polyamic acid as a major component(s). The term “major component” as used herein refers to a component contained in the largest amount in the particle composition. The amount of the major component(s) is not particularly limited, but preferably 70% by mass or more, and more preferably 85% by mass or more, of the total amount of the particle composition. When the amount of the major component(s) is within the range described above, a higher rigidity derived from the aromatic polyamide can be obtained. The aromatic polyamide preferably has a structural unit represented by any one of the following Chemical Formulae (I) to (V).

### Chemical Formula (I):

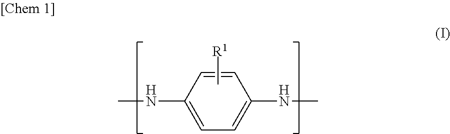

In Chemical Formula (I), R¹ represents —H, an aliphatic group having from 1 to 5 carbon atoms, —CF₃, —CCl₃, —OH, —F, —Cl, —Br, —OCH₃, a silyl group, or a group containing an aromatic ring.

### Chemical Formula (II):

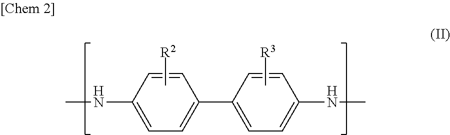

In Chemical Formula (II), each of R² and R³ represents —H, an aliphatic group having from 1 to 5 carbon atoms, —CF₃, —CCl₃, —OH, —F, —Cl, —Br, —OCH₃, a silyl group, or a group containing an aromatic ring.

### Chemical Formula (III):

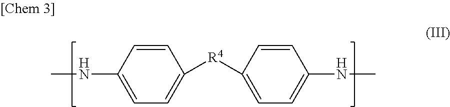

In Chemical Formula (III), R⁴ represents a group containing Si, a group containing P, a group containing S, a halogenated hydrocarbon group, a group containing an aromatic ring, or a group containing an ether bond (however, structural units having these groups may be present in a mixed state within the molecule).

### Chemical Formula (IV):

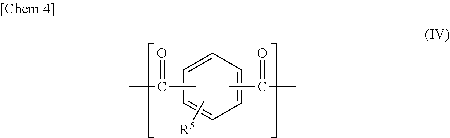

In Chemical Formula (IV), R⁵ represents an arbitrary group.

### Chemical Formula (V):

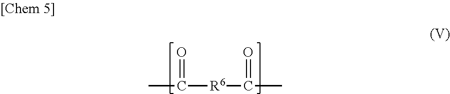

In Chemical Formula (V), R⁶ represents an arbitrary aromatic group or an arbitrary alicyclic group.

The aromatic polyamic acid preferably has a structural unit represented by any one of the following Chemical Formulae (VI) to (X).

### Chemical Formula (VI):

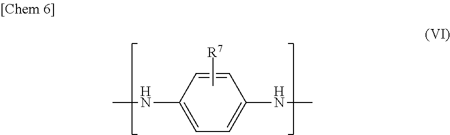

In Chemical Formula (VI), R⁷ represents —H, an aliphatic group having from 1 to 5 carbon atoms, —CF₃, —CCl₃, —OH, —F, —Cl, —Br, —OCH₃, a silyl group, or a group containing an aromatic ring.

### Chemical Formula (VII):

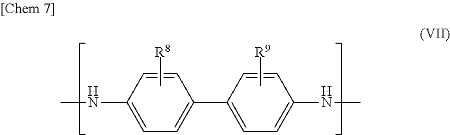

In Chemical Formula (VII), each of R⁸ and R⁹ represents —H, an aliphatic group having from 1 to 5 carbon atoms, —CF₃, —CCl₃, —OH, —F, —Cl, —Br, —OCH₃, a silyl group, or a group containing an aromatic ring.

### Chemical Formula (VIII):

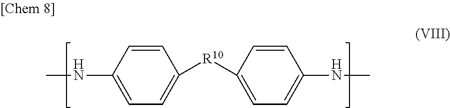

In Chemical Formula (VIII), R¹⁰ represents a group containing Si, a group containing P, a group containing S, a halogenated hydrocarbon group, a group containing an aromatic ring, or a group containing an ether bond (however, structural units having these groups may be present in a mixed state within the molecule).

### Chemical Formula (IX):

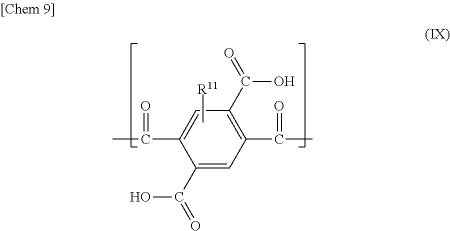

In Chemical Formula (IX), R¹ represents an arbitrary group.

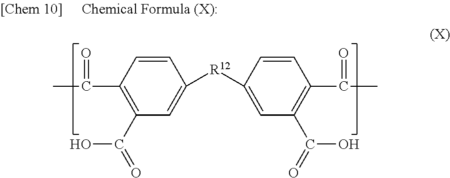

In Chemical Formula (X), R¹² represents a group containing Si, a group containing P, a group containing S, a halogenated hydrocarbon group, a group containing an aromatic ring, or a group containing an ether bond (however, structural units having these groups may be present in a mixed state within the molecule).

The particle composition according to the present invention may contain a thermosetting resin, an ultraviolet curable resin, a hydrolyzed/condensed resin, an organic-inorganic hybrid resin such as an alkoxysilane compound, and/or the like, for the purpose of improving the rigidity, thermal dimensional stability and the like. The resin composition may further contain particles. The “particles” as used herein may be either inorganic particles or organic particles. However, the particle composition preferably contains inorganic particles when it is intended to improve the hardness or the thermal dimensional stability. The inorganic particles are not particularly limited, and examples thereof include particles of oxides, silicides, nitrides, borides, chlorides, carbonates and the like, of metals and semi-metals. Specific examples thereof include particles of silica (SiO₂), aluminum oxide (Al₂O₃), zinc oxide (ZnO), zirconium oxide (ZrO₂), titanium oxide (TiO₂), antimony oxide (Sb₂O₃) and indium tin oxide (ITO). Further, the particle composition may contain an organic or inorganic pigment or dye, or an antioxidant, for the purpose of reducing coloration or deterioration.

The particle composition according to the present invention may contain a polymer other than the aromatic polyamide for the purpose of adjusting the mechanical properties, solubility and the like. Specific examples of the polymer include vinyl-based polymers; polyester, polyimide, polyether, polysulfide, polyurethane, polycarbonate, polyacetal and silicone polymers; and copolymers thereof.

When it is necessary to identify the chemical structures and the composition ratios of the aromatic polyamide and other components contained in the resin composition according to the present invention, each of the components separated by column chromatography, distillation and/or the like can be analyzed by any combination of the nuclear magnetic resonance method (NMR), Fourier transform infrared spectroscopy (FT-IR), mass spectrometry (MS), elemental analysis and the like.

The particle composition according to the present invention is characterized in that, when the particle composition is formed into an aqueous dispersion having a concentration of 100 ppm by mass, and when the average hydrodynamic radius of the particle, as measured by the dynamic light scattering method, is defined as r_{A} (nm), and the average hydrodynamic radius after subjecting the dispersion to an ultrasonic treatment is defined as r_{B} (nm), the ratio r/r_{B} is 1 or more, and r_{B} is 100 nm or more and 10,000 nm or less. When the ratio r_{A}/r_{B} is adjusted to 1 or more and r_{B} is adjusted to 100 nm or more and 10,000 nm or less, the processability can be improved because of a large particle size before being dispersed, and a high dispersibility and solubility can be obtained. To obtain the above-described effects, it is preferred that the ratio r_{A}/r_{B} be 3 or more, and TB be 100 nm or more and 5,000 nm or less; it is more preferred that the ratio r_{A}/r_{B} be 4 or more and TB be 100 nm or more and 3,500 nm or less; and it is still more preferred that the ratio r_{A}/r_{B} be 5 or more and r_{B} be 100 nm or more and 2,500 nm or less. In cases where r_{B} is less than 100 nm, the fine particles to be produced may be too fine to result in the deterioration of the processability, or the degree of polymerization may be decreased to result in a decrease in the rigidity.

In the particle composition according to the present invention, the specific surface area as measured by the gas adsorption method (BET method) is preferably 50 m²/g or more and 90 m²/g or less. The specific surface area is more preferably 55 m²/g or more and 90 m²/g or less, and still more preferably 65 m²/g or more and 90 m²/g or less. When the specific surface area is adjusted to 50 m²/g or more, it is possible to improve the dispersibility or to reduce the amount of impurities in the composition. A specific surface area of more than 90 m²/g may cause micronization, possibly resulting in the deterioration of the handleability.

In the particle composition according to the present invention, the ratio M_{w}/Mₙ of the weight-average molecular weight M_{w} and the number-average molecular weight Mₙ, as measured by gel permeation chromatography (GPC), is preferably 1.0 or more and 2.5 or less. The ratio M_{w}/Mₙ is more preferably 1.0 or more and 2.3 or less, and still more preferably 1.0 or more and 2.1 or less. When the ratio M_{w}/Mₙ is adjusted to 1.0 or more and 2.5 or less, it leads to a decrease in the amount of volatile impurities or a decrease in the amount of low-molecular-weight components that function as a plasticizer, making it possible to improve the rigidity of the resulting molded article. A ratio M_{w}/Mₙ of larger than 2.5 may lead to an increase in the amounts of low-molecular-weight oligomers and unreacted monomers that are produced as by-products during the polymerization and that remain as impurities in the composition.

Next, a method of producing the particle composition according to the present invention that contains an aromatic polyamide and/or an aromatic polyamic acid as a major component(s) will be described. However, the present invention is not limited to the following method.

In the method of obtaining the particle composition according to the present invention, first, for example, an acid dichloride and a diamine as raw materials are subjected to low-temperature solution polymerization in an aprotic polar solvent to polymerize an aromatic polyamide. The “aprotic polar solvent” as used herein refers to a polar solvent that does not have a proton (hydrogen cation) donating ability. Examples of the aprotic polar solvent include pyrrolidone-based solvents such as N-methyl-2-pyrrolidone (NMP); formamide-based solvents such as N,N-dimethylformamide; acetamide-based solvents such as N,N-dimethylacetamide; sulfoxide-based solvents such as dimethyl sulfoxide; ether-based solvents such as tetrahydrofuran; lactone-based solvents such as γ-butyrolactone; ester-based solvents such as ethyl acetate; and nitrile-based solvents such as acetonitrile. It is desired to use these solvents singly or as a mixture.

In order to inhibit the inactivation of the acid dichloride, the water content in the solvent to be used in the polymerization is preferably adjusted to 500 ppm by mass or less, and more preferably to 200 ppm by mass or less. In cases where there is a large difference in the molar ratios of the acid dichloride and the diamine, the molecular weight of the polymer to be polymerized may be decreased, possibly resulting in a failure to obtain a powder upon adding an organic poor solvent. Therefore, it is preferred to adjust the molar ratio of one of the acid dichloride and the diamine to be from 96.0 to 99.8%, more preferably from 97.0 to 99.8%, of the other. While the polymerization reaction of the aromatic polyamide is accompanied by heat generation, the temperature of the solution during the polymerization is preferably adjusted to 40° C. or lower, and more preferably to 30° C. or lower. When the solution temperature is higher than 40° C., side reactions may occur, possibly resulting in a failure to sufficiently increase the degree of polymerization.

The particle composition according to the present invention can be obtained by adding an organic poor solvent that does not dissolve the polymer to the above-described polymerization solution. Examples of the “organic poor solvent that does not dissolve the polymer” as used herein include hydrocarbon-based solvents such as hexane and cyclohexane; alcohol-based solvents such as methanol and ethanol; ketone-based solvents such as acetone; and ether-based solvents such as THF and diethyl ether.

The combination of the aprotic polar solvent to be used in the polymerization and the organic poor solvent is preferably a combination of mutually miscible solvents. It is preferred to use an acetamide-based solvent, a pyrrolidone-based solvent, a formamide-based solvent, or a mixed solvent containing any of these solvents, as the aprotic polar solvent, because the degree of polymerization of the polymer comprised in the particle composition can be improved. A specific solvent system may be, for example, a system in which 2-propanol is added to a mixed solvent of DMAc and THF; a system in which 2-propanol is added to a mixed solvent of NMP and THF; a system in which decane is added to a mixed solvent of DMAc and THF, or the like. However, the solvent system is not limited to these combinations. The method of incorporating an organic-inorganic hybrid resin and/or particles to the particle composition is not particularly limited. However, it is preferred to add the resin and/or particles directly to the polymerization solution after the polymerization process, or to add the resin and/or particles as a solution dispersed in an organic poor solvent. In case the resin and/or particles is/are added before the polymerization process, the particles may inhibit the polymerization reaction, possibly resulting in a decrease in the molecular weight of the polymer or in a failure to obtain the resin composition.

The particle composition according to the present invention can be suitably used as a raw material of fibers, a molded product, a film or the like. In particular, the particle composition is preferably used as a film raw material. Since a film having a high rigidity and with a low amount of impurities can be obtained, the resin composition can be suitably used as a raw material of the material for any of various applications, such as a display material, a sensor substrate, a circuit board, an optical wave-guide substrate, a substrate for mounting a semiconductor, a transparent conductive film, a phase-difference film, a touch-panel substrate, a solar cell, a packaging material, a pressure-sensitive adhesive tape, an adhesive tape, a decorative material, or the like.

The film according to the present invention as characterized in that the particle composition described above is used as a raw material. The use of the above-described particle composition as a raw material leads to a decrease in the amount of low-molecular-weight components of the polymer included in the film, making it possible to form a film having an excellent rigidity and long-term stability. Further, the amount of impurities contained in the film can be decreased, making it possible to reduce the coloration or clouding of the film. The film according to the present invention preferably has a thickness of 1 μm or more and 100 μm or less, and more preferably 3 μm or more and 80 μm or less, but is not particularly limited thereto. The film according to the present invention preferably has a Young's modulus of 8.0 GPa or more and 12.0 GPa or less from the viewpoints of the shape stability and the mechanical strength. The film in the present invention preferably has a long-term heat resistance temperature of 160° C. or higher, and more preferably 170° C. or higher. To adjust the long-term heat-resistance temperature within the range described above, it is preferred to use a particle composition that does not contain components with a low degree of polymerization, by-products and impurities as a raw material. In the present invention, the “long-term heat-resistance temperature” refers to the temperature at which the Young's modulus is decreased by half with respect to the value at 25° C., and a higher long-term heat-resistance temperature indicates a better long-term stability.

The film according to the present invention can be obtained by coating a resin solution obtained by dissolving the above-described particle composition on a substrate, followed by film formation. The solvent for dissolving the particle composition is not particularly limited. From the viewpoint that a homogeneous solution can be easily obtained, however, the solvent may be, for example, a pyrrolidone-based solvent such as N-methyl-2-pyrrolidone, a formamide-based solvent such as N,N-dimethylformamide, an acetamide-based solvent such as N,N-dimethylacetamide, or dimethyl sulfoxide. The formation of the film according to the present invention can be performed, for example, by a method such as a wet-dry method in which the coated substrate is subjected to a heat treatment after having undergone a pre-drying step and a washing step in a wet bath; a dry method in which the coated substrate is subjected to solvent drying without undergoing a washing step; or a wet method in which the coated substrate is introduced into a wet bath without undergoing a solvent drying step and then subjected to a heat treatment; or the like. The film formation can be performed by any of the above-described methods. However, the film formation is preferably performed by the dry method, from the viewpoints of the ease of the step and the processability that a film can be formed on any object.

The method of coating the resin solution on a substrate can be selected from known methods such as a coating method using a mouthpiece or die, a roller coating method, a wire bar coating method and a gravure coating method. The substrate can be any material that is not corroded by a raw material solution and that is not deformed or degraded by heating for solvent drying. The substrate may be, for example, a glass plate, a thin film glass, a resin film, a metal plate, a quartz plate, a silicon wafer or the like. Further, the substrate may have a smooth surface, a microstructure, or a patterned structure having a pattern in the form of a lens, a diffraction grating or the like, as the surface structure.

The solvent drying can be performed, for example, by a method such as hot-air drying, infrared irradiation or microwave irradiation, but is not particularly limited thereto. The solvent drying is preferably performed at a temperature range from 50 to 400° C. It is more preferred that the drying step include the step of drying within a temperature range from 150° C. to 400° C., from the viewpoint of improving the thermal dimensional stability and the like. It is still more preferred to carry out a preliminary drying at a temperature from 50 to 200° C., and then carry out the solvent drying at a temperature from 200 to 400° C., for the purpose of preventing surface roughening due to sudden solvent evaporation.

The optical lens and the diffractive optical element according to the present invention are each characterized in that the particle composition described above is used as a raw material. The use of the above-described particle composition as a raw material reduces the coloration or devitrification caused by impurities, making it possible to improve the shape stability. Further, it is possible to obtain an excellent refractive index derived from the fact that the aromatic polyamide and the aromatic polyamic acid have a high dielectric constant. When it is intended to achieve a high refractive index, it is preferred that the aromatic polyamide and/or the aromatic polyamic acid each contains, within its structure, a functional group with a high dielectric constant or a functional group that reduces the molecular volume. Such a functional group may be, for example, a halogen group (Br or I), a group containing a sulfur atom, or a group capable of forming a hydrogen bond such as hydroxy group. This allows for improving the sensitivity and the luminance, for example, in cases where the optical lens or the diffractive optical element is used in an application of a lens for a sensor or a device for AR.

The optical lens can be produced, for example, by a method in which the above-described resin solution is filled into a mold in the form of an optical member or cast on a substrate in the form of an optical lens, after which desolventization is carried out under high-temperature conditions. It is also possible to mold the particle composition in the form of a rod or a plate, followed by machining and polishing, to form into an optical lens. The diffractive optical element can be produced, for example, by a method in which the above-described resin solution is coated on a substrate having a diffraction-grating pattern, followed by drying the solvent, or a method in which the particle composition molded in the form a plate is machined with a laser or the like to form a diffraction grating pattern.

The optical lens or the diffractive optical element according to the present invention can be suitably used as an optical member such as a lens for a semiconductor sensor, an optical wave-guide circuit or a device for AR.

The ion conductive film and the battery separator film according to the present invention are each characterized in that the resin composition described above is used as a raw material. The above-described particle composition is different from a conventional polyamide-based resin in that the particle composition does not contain any by-products or inorganic salts. Therefore, the incorporation of impurities can be prevented, enabling the prevention of ions moving within the film from being captured by, or reacting with, the impurities that stabilize ion conductive properties. Further, the mechanical strength is increased due to a decrease in the amount of low-molecular-weight components. As a result, rupture or the like is less likely to occur when a compressive force, a bending stress, an impact or the like is applied, making it easier to maintain film properties.

Each of the ion conductive film and the battery separator film according to the present invention may be a single film or may be a laminated film formed on at least one surface of an electrode material or a porous substrate. In the case of forming a single film, the film can be produced in the same manner as in the production of the film described above.

In the case of forming a laminated film formed on an electrode material, the electrode may be either a positive electrode or a negative electrode, and the laminated film can be used for a lithium metal electrode, a carbon electrode or the like. In the case of using the laminated film for a lithium metal negative electrode, for example, the film functions as if it is a protective film, by forming the film according to the present invention directly on the lithium negative electrode, making it possible to improve the ion conductivity or dendrite resistance.

In the case of forming a laminated film formed on a porous substrate, the porous substrate may be, for example, a porous film, a nonwoven fabric, a porous film sheet composed of a fibrous product, or the like, and may have through pores. The porous substrate is preferably made of a resin that has electrical insulating properties, that is electrically stable, and that is also stable in an electrolyte solution. Further, from the viewpoint of imparting a shutdown function, the resin to be used is preferably a thermoplastic resin, and more preferably a thermoplastic resin having a melting point of 200° C. or lower. The “shutdown function” as used herein refers to the function of the thermoplastic resin to melt due to heat, and to block the pores of the porous structure, when abnormal heat generation occurs in a lithium-ion battery, thereby stopping the ion movement and power generation.

The porous substrate is preferably a polyolefin porous substrate containing a polyolefin, and more preferably a polyolefin porous substrate containing a polyolefin having a melting point of 200° C. or lower. The polyolefin may specifically be, for example, polyethylene, polypropylene, or a copolymer or a mixture thereof. The polyolefin porous substrate may be, for example, a single-layer polyolefin porous substrate containing 90% by mass or more of polyethylene, a multilayer polyolefin porous substrate composed of polyethylene and polypropylene, or the like.

The film resistance of the ion conductive film or the battery separator film according to the present invention can be determined by sandwiching the resin film impregnated with an electrolyte solution between SUS metal plates and measuring the alternating current impedance. The electrolyte solution to be used at this time is an electrolyte solution obtained by dissolving LiPF₆, as a solute, in a mixed solvent of ethylene carbonate and diethyl carbonate, mixed at a ratio of ethylene carbonate:diethyl carbonate of 1:1 (volume ratio) to a concentration of 1.0 mol/L. The alternating current impedance is measured in an atmosphere of 25° C., under the conditions of a voltage amplitude of 10 mV and a frequency of from 10 Hz to 5,000 kHz, after allowing the above-described resin film to stand for 12 hours in an atmosphere of 50° C. to perform a doping treatment. Thereafter, the film resistance (Q) can be determined from the Cole-Cole plot. Each of the ion conductive film and the battery separator film according to the present invention preferably has a film resistance, as measured under the conditions described above, of from 0.05 to 50.0 Ω·cm². When the film resistance is adjusted within the range described above, a high ion conductivity is obtained when used as a solid electrolyte film, making it possible to obtain excellent output characteristics and cycle characteristics. A film resistance of more than 50.0 Ω·cm² leads to a low ion conductivity when used as a solid electrolyte film, resulting in a decrease in the output characteristics or in an increase in capacity deterioration upon repeated use. To adjust the film resistance within the range described above, it is preferred to create in the film minute-free volume through which lithium ions can move. For example, the aromatic polyamide and/or aromatic polyamic acid each preferably has a fluorine atom or a macrocyclic structure in the molecular structure.

Each of the ion conductive film and the battery separator film according to the present invention can be suitably used in a secondary battery, a vehicle, an aerial vehicle or an electronic device. The “vehicle” in the present invention refers to a vehicle that includes a secondary battery as a part of the power mechanism, such as an automobile, a motorcycle, a bicycle, an electric wheelchair, an electric cart or the like. The “aerial vehicle” in the present invention refers to an aerial vehicle that includes a secondary battery as a part of the propulsion mechanism, such as a manned aerial vehicle, an unmanned aerial vehicle, a drone or the like. The “electronic device” in the present invention generally refers to a device that includes a secondary battery as a power-storage device. Electric optical devices and information terminal devices are both electronic devices.

The circuit board according to the present invention is characterized in that the particle composition described above is used as a raw material. The use of the above-described particle composition as a raw material leads to a decrease in the linear expansion coefficient, making it possible to obtain an excellent heat resistance.

The circuit board according to the present invention can be obtained by forming wiring on a resin film that serves as a substrate. The resin film that serves as a substrate can be produced in the same manner as in the production of the film described above. Reinforcing fibers may be added for the purpose of reinforcing the resulting substrate. Examples of the reinforcing fibers include glass fibers; metal fibers; other synthetic and natural inorganic fibers; natural fibers such as cotton, hemp and felt fibers; and carbon fibers. It is possible to add a single kind of reinforcing fiber or two or more kinds thereof in combination.

In the circuit board according to the present invention, the wiring may be formed on one surface or both surfaces of the resin film. The wiring can be formed, for example, by a method of patterning an electrically conductive material on the resin film, such as, for example, the lamination method, the metallizing method, the sputtering method, the vapor deposition method, the coating method or the printing method. Examples of the electrically conductive material include metals such as copper, silver and gold; indium tin oxide (ITO); and electrically conductive resins such as polythiophene, polyaniline and polypyrrole. Before the patterning of the electrically conductive material, the surface of the resin film may be modified by a plasma treatment or the like, or an adhesive may be applied on the resin film, for the purpose of improving the adhesion between the resin film and the electrically conductive material.

The circuit board according to the present invention can be suitably used in a precision instrument or a flexible device.

The diaphragm according to the present invention is characterized in that the particle composition described above is used as a raw material. The use of the above-described particle composition as a raw material allows for obtaining a high Young's modulus, making it possible to produce a diaphragm having excellent creep properties and an excellent output in the high-frequency range. The diaphragm according to the present invention preferably has a film thickness of 5 μm or more and 50 μm or less. When the diaphragm has a film thickness of 5 μm or more, a high mechanical strength and a good handling performance can be obtained. When the film thickness is adjusted to 50 μm or less, good transient characteristics can be more easily obtained.

The diaphragm according to the present invention may be a flat film or may have an arbitrary shape such as the shape of a cone or a bellows. In the case of forming a flat film, the film can be produced in the same manner as in the production of the film described above. In the case of forming a diaphragm having an arbitrary shape, the diaphragm can be produced, for example, by a method in which the flat film is cut, pasted, bent, etc.; a method in which the flat film is pressed with a mold to transfer the shape; a method in which the above-described solution is coated on a mold to directly obtain a film having an arbitrary shape; or the like. However, any of these methods can be used. The diaphragm according to the present invention can be suitably used as a member of an acoustic speaker, a microphone, an ultrasonic actuator or an ultrasonic sensor.

### EXAMPLES

The present invention will now be described more specifically with reference to Examples.

The measurements of physical properties and the evaluation of effects in the present invention were carried out in accordance with the following methods.

### (1) Ultrasonic Treatment

The ultrasonic treatment of the solution was carried out using the following apparatus and under the following conditions. A glass tube containing 10 mL of a sample solution was immersed in an ultrasonic cleaner (BRANSONIC 220; output/frequency: 75 W/45 kHz; manufactured by Yamato Scientific Co., Ltd.), filled with water, and shaken.

### (2) Average Hydrodynamic Radius (Average Particle Size)

The particle composition was dispersed in pure water to a concentration of 100 ppm by mass to obtain a solution, and the resulting solution was subjected to the measurement of the cumulant average particle radius by the dynamic light scattering method, using the following apparatus and under the following conditions. The particle radius obtained from the solution that had not been subjected to the ultrasonic treatment was defined as r_{A}(nm), and the particle radius obtained from the solution one hour after the ultrasonic treatment was defined as r_{B} (nm).
Apparatus: ELSZ-1000 (manufactured by Otsuka Electronics Co., Ltd.)
Measurement conditions: in accordance with JIS-Z8826 (2005)

### (3) Specific Surface Area

The particle composition was degassed under reduced pressure in a glass cell at room temperature for 12 hours, and the resulting composition was subjected to the measurement of the specific surface area, using the following apparatus and under the following conditions.
Apparatus: BELSORP-max (manufactured by Nippon Bell Co., Ltd.)
Adsorbent: krypton gas
Gas for measuring dead volume: helium gas
Measurement temperature: 77 K
Saturated vapor pressure: 0.331 kPa
Method for analyzing specific surface area: Brunauer-Emmett-Teller (BET) multilayer
adsorption multi-point method
Measurement conditions: in accordance with JIS-Z8830 (2013)

### (4) Average Molecular Weight

The particle composition was dissolved in a solvent for measurement at 60° C. to a concentration of 1.0 g/L, and then filtered through a 0.5 μm filter to obtain a solution. The thus-obtained solution was subjected to the measurements of the number-average molecular weight Mₙ and the mass-average molecular weight M_{w}, using the following apparatus and under the following conditions.
Apparatus: gel permeation chromatograph No. GPC-26 (manufactured by Toray Research Center, Inc.)
Detector: differential refractive index detector RID-20A (manufactured by Shimadzu Corporation)
Columns: TSK-gel α-M, two columns ((p 7.8 mm×30 cm; manufactured by Tosoh Corporation)
Eluent: 0.05 M lithium chloride, 0.1% by mass phosphoric acid-added dimethylacetamide
Flow velocity: 0.8 mL/mm
Column temperature: 40° C.
Injection volume: 0.2 mL
Standard sample: monodisperse polystyrene (manufactured by Tosoh Corporation)

### (5) Confirmation of Solubility

The solubility of the particle composition was evaluated as follows.

The particle composition was added to NMP to a concentration of 10% by mass, and the resulting solution was subjected to the ultrasonic treatment at 60° C. At this time, those in which the complete dissolution of the particle composition was confirmed by visual observation 10 minutes after the start of the ultrasonic treatment were evaluated as “Good.” Of those in which remaining sediments were observed, those in which the complete dissolution of the particle composition was confirmed after an additional 20-minute ultrasonic treatment were evaluated as “Acceptable,” and those with remaining solids were evaluated as “Not acceptable.”

### (6) Confirmation of Processability

The processability of the particle composition was evaluated using the angle of repose as an index. The smaller the angle of repose, the higher the fluidity and the jet properties of the particle composition, indicating that the composition is more difficult to handle. The angle of repose of each particle composition was measured as follows, by the funnel-injection method (free deposition method).

The particle composition was dropped from a height of 15 cm onto a measurement table having a diameter of 5 cm, using a funnel having an inner diameter of 5 mm, in an air atmosphere controlled to a temperature of 25° C. and a humidity of 60% RH, and the particle composition was allowed to deposit in the form of a cone. The angle formed by the side surface of the cone and the measurement table (bottom face of the cone) was read with a protractor to determine the angle of repose.

### (7) Amount of Volatile Impurities

The amount of volatile impurities in the particle composition was measured using the following apparatus and method.
Apparatus: thermogravimetric apparatus TGA-50 (manufactured by Shimadzu Corporation), thermal analysis system TA-60WS (manufactured by Shimadzu Corporation)
Measurement atmosphere: nitrogen gas (20 mL/min)
Measurement temperature: from 25 to 330° C.
Temperature rise rate: 5° C./min.

### (8) Young's Modulus

A sample obtained by cutting the film into a width of 10 mm and a length 150 mm was subjected to a tensile test using a Robot Tensilon AMF/RTA-100 (manufactured by Orientec Co., Ltd.) under the conditions of a distance between chucks of 50 mm, a tensile speed of 300 mm/min, a temperature of 23° C. and a relative humidity of 65%, and the Young's modulus was determined from the resulting load-elongation curve. The test was carried out in the cast direction (longitudinal direction) of the film, and in the direction orthogonal thereto (width direction). The test was repeated five times in both directions to determine the mean value in each direction. Table 1 shows a higher value of the Young's moduli in both directions.

### (9) Long-Term Stability (Long-Term Heat Resistance Temperature)

A sample obtained by cutting the film to a width of 10 mm and a length 150 mm was subjected to a tensile test using a Tensilon universal tester RTF 1210 (manufactured by A&D Company, Limited) and a thermostatic chamber for a tensile tester (manufactured by Orientec Co., Ltd.) under the conditions of a distance between chucks of 50 mm, a tensile speed of 300 mm/min and a relative humidity of 65%. The tensile test was carried out five times at each of the temperatures of 25° C., 50° C. and 70° C., and the mean value at each temperature was determined as the Young's modulus at the temperature. The resulting Young's moduli were plotted logarithmically against temperature, approximated by a straight line by the least-squares method to extrapolate the Arrhenius plot, and the temperature at which the Young's modulus is decreased by half with respect to the value at 25° C. was determined. This temperature was defined as the long-term heat-resistance temperature. The long-term stability was evaluated as “Good” when the long-term heat-resistance temperature is 170° C. or higher, evaluated as “Acceptable” when the temperature is less than 170° C. and 160° C. or higher, and evaluated as “Not acceptable” when the temperature is less than 160° C. The evaluation results are shown in Table 1.

### Example 1

In a polymerization solvent obtained by mixing dehydrated dimethylacetamide (DMAc) and tetrahydrofuran (THF) to a volume ratio of 1:1, 2-chloro-1,4-phenylenediamine (CTPA) in an amount corresponding to 85% by mole, and 4,4′-diaminodiphenyl ether (DPE) in an amount corresponding to 15% by mole, as diamines, with respect to the total amount of the diamines, were dissolved under a nitrogen gas stream, and the resulting solution was cooled to a liquid temperature of 5° C. in an ice water bath. To the resulting solution, 2-chloroterephthaloyl chloride (CTPC) in an amount corresponding to 99% by mole with respect to the total amount of the diamines was added over 30 minutes, in a state where the interior of the system was maintained under a nitrogen gas stream and in an ice water bath. After adding the total amount of CTPC, the resulting mixture was stirred for about two hours to polymerize an aromatic polyamide (polymer A). To the resulting solution, 2-propanol, as a poor solvent, in an amount of 100% by volume with respect to the polymerization solvent, was added over 30 minutes. After the completion of the dropwise addition, the solution was stirred for another 30 minutes. Thereafter, solid components were separated by suction filtration and dried in a hot-air oven at 80° C. for one hour, and then at 120° C. for 12 hours, to obtain a particle composition containing the polymer A as a major component. At this time, a safety oven SPH100 (manufactured by Espec Corp.) was used as the hot-air oven, and the oven was used one hour after the temperature display indicated that the set temperature has been reached with the opening/closing damper set to 50%. The thus-obtained particle composition was dissolved in NMP to a concentration of 10% by mass. The resulting solution was cast on a glass plate in the form of a film using an applicator, at room temperature, and dried in the hot-air oven at 150° C. for 20 minutes and then at 280° C. for five minutes, to obtain a film having a thickness of 5 μm. The physical properties of the resulting particle composition and film are shown in Table 1. The long-term heat-resistance temperature of the film was 173° C.

### Example 2

A particle composition containing an aromatic polyamide (polymer B) as a major component was obtained in the same manner as in Example 1, except that 2,2′-bis (trifluoromethyl)-4,4′-diaminobiphenyl (TFMB), as a diamine, in an amount corresponding to 100% by mole with respect to the total amount of the diamine, and CTPC, as an acid chloride, in an amount corresponding to 99% by mole with respect to the total amount of the diamine, were used as raw material monomers; and decane was used as the poor solvent. A film was obtained in the same manner as in Example 1, except for using the thus-obtained particle composition. The physical properties of the resulting particle composition and film are shown in Table 1. The long-term heat-resistance temperature of the film was 170° C.

### Example 3

A particle composition containing the polymer A as a major component and a film using the same were obtained in the same manner as in Example 1, except that a mixed solvent of DMAc (60% by volume) and dibutyl ether (40% by volume) was used as the polymerization solvent, and ethanol was used as the poor solvent. The physical properties of the resulting particle composition and film are shown in Table 1. The long-term heat-resistance temperature of the film was 174° C.

### Example 4

A particle composition containing the polymer A as a major component and a film using the same were obtained in the same manner as in Example 1, except that a mixed solvent of DMAc (80% by volume) and THF (20% by volume) was used as the polymerization solvent, and ethanol was used as the poor solvent. The physical properties of the resulting particle composition and film are shown in Table 1. The long-term heat-resistance temperature of the film was 169° C.

### Example 5

A particle composition containing the polymer A as a major component and a film using the same were obtained in the same manner as in Example 1, except that a mixed solvent of DMAc (90% by volume) and THF (10% by volume) was used as the polymerization solvent, and 2-propanol was used as the poor solvent. The physical properties of the resulting particle composition and film are shown in Table 1. The long-term heat-resistance temperature of the film was 168° C.

### Example 6

A particle composition containing the polymer A as a major component and a film using the same were obtained in the same manner as in Example 1, except that a mixed solvent of NMP (95% by volume) and THF (5% by volume) was used as the polymerization solvent, and 2-propanol was used as the poor solvent. The physical properties of the resulting particle composition and film are shown in Table 1. The long-term-heat resistance temperature of the film obtained using the thus obtained particle composition was 168° C.

### Example 7

In a polymerization solvent obtained by mixing dehydrated dimethylacetamide (DMAc) and tetrahydrofuran (THF) to a volume ratio of 1:1, TFMB, as a diamine, in an amount corresponding to 100% by mole with respect to the total amount of the diamine, was dissolved under a nitrogen gas stream at room temperature. To the resulting solution, 4,4′-(hexafluoroisopropylidene)diphthalic anhydride (6FDA) in an amount corresponding to 99% by mole with respect to the total amount of the diamine was added over 30 minutes. After adding the total amount of 6FDA, the resulting mixture was stirred for about two hours to polymerize an aromatic polyamic acid (polymer C). The resulting solution was cooled using an ice water bath, and 2-propanol, as a poor solvent in an amount of 100% by volume with respect to the polymerization solvent, was added over 30 minutes. After the completion of the dropwise addition, the solution was stirred for another 30 minutes. Thereafter, solid components were separated by suction filtration, and dried in a hotair oven at 80° C. for one hour, and then at 100° C. for 12 hours, to obtain a particle composition containing the polymer C as a major component. At this time, a safety oven SPH100 (manufactured by Espec Corp.) was used as the hot-air oven, and the oven was used one hour after the temperature display indicated that the set temperature has been reached with the opening/closing damper set to 50%. The thus-obtained particle composition was dissolved in NMP to a concentration of 10% by mass. The resulting solution was cast on a glass plate in the form of a film, using an applicator, at room temperature, and dried in the hot-air oven at 150° C. for 20 minutes and then at 280° C. for five minutes, followed by a heat treatment at 350° C. for 10 minutes, to obtain a film having a thickness of 5 μm. The physical properties of the resulting particle composition and film are shown in Table 1. The long-term-heat resistance temperature of the film was 181° C.

### Example 8

A particle composition obtained in the same manner as in Example 2 was dissolved in NMP to a concentration of 10% by mass. The resulting solution was cast on a glass plate in the form of a film using an applicator, at room temperature, and dried in the hot-air oven at 150° C. for 20 minutes and then at 280° C. for three minutes, to obtain a film having a thickness of 3 μm. The physical properties of the resulting particle composition and film are shown in Table 1. The long-term-heat resistance temperature of the film was 170° C.

### Example 9

A particle composition obtained in the same manner as in Example 2 was dissolved in NMP to a concentration of 10% by mass. The resulting solution was cast on a glass plate in the form of a film using an applicator, at room temperature, and dried in the hot-air oven at 150° C. for 20 minutes and then at 280° C. for three minutes, to obtain a film having a thickness of 1 μm. The physical properties of the resulting particle composition and film are shown in Table 1. The long-term-heat resistance temperature of the film was 164° C.

### Example 10

A particle composition obtained in the same manner as in Example 2 was dissolved in NMP to a concentration of 10% by mass. The resulting solution was cast on a glass plate in the form of a film using an applicator, at room temperature, and dried in the hot-air oven at 150° C. for 20 minutes and then at 280° C. for five minutes, to obtain a film having a thickness of 50 μm. The physical properties of the resulting particle composition and film are shown in Table 1. The long-term-heat resistance temperature of the film was 176° C.

### Example 11

A particle composition obtained in the same manner as in Example 2 was dissolved in NMP to a concentration of 10% by mass. The resulting solution was cast on a glass plate in the form of a film using an applicator, at room temperature, and dried in the hot-air oven at 150° C. for 20 minutes and then at 280° C. for seven minutes, to obtain a film having a thickness of 78 μm. The physical properties of the resulting particle composition and film are shown in Table 1. The long-term-heat resistance temperature of the film was 176° C.

### Example 12

A particle composition obtained in the same manner as in Example 2 was dissolved in NMP to a concentration of 10% by mass. The resulting solution was cast on a glass plate in the form of a film using an applicator, at room temperature, and dried in the hot-air oven at 150° C. for 20 minutes and then at 280° C. for 10 minutes, to obtain a film having a thickness of 97 μm. The physical properties of the resulting particle composition and film are shown in Table 1. The long-term-heat resistance temperature of the film was 178° C.

### Comparative Example 1

In dehydrated N-methyl-2-pyrrolidone (NMP), 85% by mole of CTPA and 15% by mole of DPE, as diamines, were dissolved under a nitrogen gas stream, and the resulting solution was cooled to a liquid temperature of 5° C. in an ice water bath. To the resulting solution, CTPC in an amount corresponding to 99% by mole with respect to the total amount of the diamines was added over 30 minutes, in a state where the interior of the system was maintained under a nitrogen gas stream and in an ice water bath. After adding the total amount of CTPC, the resulting mixture was stirred for about two hours, to polymerize an aromatic polyamide (polymer A). The resulting polymerization solution was added to a large amount of pure water while stirring to allow the polymer A to solidify in the form of fibers. The solidified polymer A was retrieved, ground in a mixer for five minutes, and dried in a hot-air oven at 80° C. for one hour, and then in a vacuum oven at 120° C. for 12 hours, to obtain a particle composition containing the polymer A as a major component. A film was obtained in the same manner as in Example 1, except for using the thus-obtained particle composition. The physical properties of the resulting particle composition and film are shown in Table 1. The long-term-heat resistance temperature of the film was 155° C.

### Comparative Example 2

A particle composition obtained in the same manner as in Comparative Example 1 was dissolved in NMP to obtain a polymer solution. The resulting polymer solution (8% by mass) was coated on a 100 μm polyethylene terephthalate (PET) film with a die coater, in the form of a film having a thickness of 120 μm, and treated for two minutes in humidity-controlled air at a temperature of 30° C. and a relative humidity of 85% RH. Thereafter, the devitrified film was peeled off the PET film, and then introduced into a water bath at 60° C. for two minutes, to perform solvent extraction. Subsequently, the resulting film was dried in a tenter, first at 90° C. for one minute. Finally, the dried film was heat treated at 250° C. for two minutes using a hot-air oven to obtain a porous film. The thus-obtained porous film was ground in a mixer to obtain a particle composition containing the polymer A as a major component. A film was obtained in the same manner as in Example 1, except for using the thus-obtained particle composition. The physical properties of the resulting particle composition and film are shown in Table 1. The long-term-heat resistance temperature of the film was 150° C.

### Comparative Example 3

Using a preparative GPC (Prominence, manufactured by Shimadzu Corporation), regional components showing an intensity of 20% or more with respect to the maximum peak intensity detected by a differential refractive index detector (RID-10A, manufactured by Shimadzu Corporation) were preparatively separated, from a polymer polymerized in the same manner as in Comparative Example 1, to obtain a polymer solution. The resulting polymer solution was added to a large amount of pure water while stirring to allow the polymer A to solidify in the form of fibers. The solidified polymer A was retrieved, ground, and dried in a hot-air oven at 80° C. for one hour, and then in a vacuum oven an at 120° C. for 12 hours, to obtain a particle composition containing the polymer A as a major component. A film was obtained in the same manner as in Example 1, except for using the thus-obtained particle composition. The physical properties of the resulting particle composition and film are shown in Table 1. The long-term-heat resistance temperature of the film was 168° C.

### Comparative Example 4

The same procedure as in Comparative Example 1 was carried out, except that the polymer was ground in a mixer for one minute, to obtain a particle composition containing the polymer A as a major component. A film was obtained in the same manner as in Example 1, except for using the thus-obtained particle composition. The physical properties of the resulting particle composition and film are shown in Table 1. The long-term-heat resistance temperature of the film was 153° C.

### Comparative Example 5

A polymer solution obtained in the same manner as in Comparative Example 1 was diluted with NMP so that the ratio of the polymer component was 0.10% by mass. A large amount of pure water was added dropwise to the resulting diluted solution while stirring, to suspend the solution, followed by filtration, to obtain a particle composition containing the polymer A as a major component. A film was obtained in the same manner as in Example 1, except for using the thus-obtained resin composition. The physical properties of the resulting particle composition and film are shown in Table 1. The long-term-heat resistance temperature of the film was 157° C.

TABLE 1

| | Resin Composition | | | | | | | | | | |
|---|---|---|---|---|---|---|---|---|---|---|---|
| | | | | | | | | Amount of | | | |
| | | | | | | | | residual | Film | | |
| | | | | BET specific | | | Angle of | volatile | Film | Young's | |
| | | r_{A}/r_{B} | /r_{B} | surface area | M_{w}/Mₙ | | repose | matter | thickness | modulus | Long-term |
| | Polymer | (—) | (nm) | (m²/g) | (—) | Solubility | (°) | (% by mass) | (μm) | (Gpa) | stability |
| Example 1 | A | 6.7 | 2410 | 71 | 2.1 | Good | 50 | 0.5 | 5 | 9.1 | Good |
| Example 2 | B | 5.2 | 2350 | 68 | 2.5 | Good | 48 | 0.7 | 5 | 8.6 | Good |
| Example 3 | A | 6.5 | 102 | 75 | 1.8 | Good | 51 | 0.5 | 5 | 9.3 | Good |
| Example 4 | A | 5.0 | 2480 | 51 | 2.6 | Good | 45 | 2.7 | 5 | 8.4 | Acceptable |
| Example 5 | A | 4.8 | 3320 | 47 | 2.8 | Acceptable | 42 | 3.4 | 5 | 8.3 | Acceptable |
| Example 6 | A | 3.1 | 4740 | 48 | 2.7 | Acceptable | 35 | 3.1 | 5 | 8.3 | Acceptable |
| Example 7 | C | 3.0 | 3560 | 51 | 2.3 | Good | 37 | 2.8 | 5 | 6.5 | Good |
| Example 8 | B | 5.2 | 2350 | 68 | 2.5 | Good | 48 | 0.7 | 3 | 8.6 | Good |
| Example 9 | B | 5.2 | 2350 | 68 | 2.5 | Good | 48 | 0.7 | 1 | 8.5 | Acceptable |
| Example 10 | B | 5.2 | 2350 | 68 | 2.5 | Good | 48 | 0.7 | 50 | 8.3 | Good |
| Example 11 | B | 5.2 | 2350 | 68 | 2.5 | Good | 48 | 0.7 | 78 | 8.2 | Good |
| Example 12 | B | 5.2 | 2350 | 68 | 2.5 | Good | 48 | 0.7 | 97 | 8.0 | Good |
| Comparative | A | 2.8 | 5830 | 46 | 2.6 | Not | 55 | 4.0 | 5 | 8.6 | Not |
| Example 1 | | | | | | acceptable | | | | | acceptable |
| Comparative | A | 2.8 | 5100 | 53 | 2.8 | Not | 53 | 2.9 | 5 | 8.4 | Not |
| Example 2 | | | | | | acceptable | | | | | acceptable |
| Comparative | A | 2.4 | 5810 | 38 | 2.2 | Not | 53 | 3.4 | 5 | 8.9 | Good |
| Example 3 | | | | | | acceptable | | | | | |
| Comparative | A | 2.0 | 10200 | 42 | 2.6 | Not | 62 | 4.7 | 5 | 8.5 | Not |
| Example 4 | | | | | | acceptable | | | | | acceptable |
| Comparative | A | 1.2 | 95 | 93 | 2.9 | Good | 18 | 0.6 | 5 | 8.2 | Not |
| Example 5 | | | | | | | | | | | acceptable |

1. A particle composition comprising an aromatic polyamide and/or an aromatic polyamic acid,
wherein, r_{A}/r_{B} is larger than 1, and r_{B} is 100 nm or more and 10,000 nm or less,
in which
r_{A} (nm) is an average hydrodynamic radius of particles as measured by a dynamic light scattering method in an aqueous dispersion containing said particle composition at a concentration of 100 ppm by mass, and
r_{B} (nm) is said average hydrodynamic radius after subjecting the aqueous dispersion to an ultrasonic treatment.

2. The particle composition according to claim 1, wherein
the particle composition comprises the aromatic polyamide,
r_{A}/r_{B} is 3 or more, and
r_{B} is 100 nm or more and 5,000 nm or less.

3. The particle composition according to claim 1, wherein a Brunauer-Emmett-Teller (BET) surface area of the particle composition as measured by a gas adsorption method is 50 m²/g or more and 90 m²/g or less.

4. The particle composition according to claim 1, wherein M_{w}/Mₙ is 1.0 or more and 2.5 or less,
in which Mₙ, is a number average molecular weight as measured by gel permeation chromatography (GPC), and M_{w}, is a mass average molecular weight as measured by GPC.

5. A film comprising the particle composition according to claim 1.

6. An optical lens comprising the particle composition according to claim 1.

7. A diffractive optical element comprising the particle composition according to claim 1.

8. An ion conductive film comprising the particle composition according to claim 1.

9. A battery separator film comprising the particle composition according to claim 1.

10. A secondary battery comprising the ion conductive film according to claim 8.

11. A circuit board comprising the particle composition according to claim 1.

12. A diaphragm comprising the particle composition according to claim 1.

13. The particle composition according to claim 1, wherein the aromatic polyamide is a major component in the particle composition.

14. The particle composition according to claim 1, wherein the aromatic polyamic acid is a major component in the particle composition.

15. The particle composition according to claim 1, wherein a concentration of the aromatic polyamide is 70% by mass or more.

16. The particle composition according to claim 1, wherein a concentration of the aromatic polyamic acid is 70% by mass or more.

17. The particle composition according to claim 1, wherein a total concentration of the aromatic polyamide and the aromatic polyamic acid is 70% by mass or more.
